(19) United States
(12) Patent Application Publication
(10) Pub. No.: US 2026/0206305 A1
(43) Pub. Date: Jul. 16, 2026

(54) SEMICONDUCTOR DEVICE

(71) Applicant: Vanguard International Semiconductor Corporation, Hsinchu (TW)

(72) Inventors: Chen-Dong Tzou, Taipei City (TW); Yun-Kai Lai, Taichung City (TW); Chih-Cherng Liao, Hsinchu City (TW); Chia-Hao Lee, Hsinchu County (TW)

(73) Assignee: Vanguard International Semiconductor Corporation, Hsinchu (TW)

(21) Appl. No.: 19/026,301

(22) Filed: Jan. 16, 2025

(51) Int. Cl. H10D 84/83; H10D 30/01; H10D 30/65; H10D 30/66; H10D 64/00; H10D 64/23; H10D 84/01; H10D 84/85

(52) U.S. Cl. CPC H10D 84/839; H10D 30/65; H10D 30/665; H10D 30/668; H10D 64/112; H10D 64/117; H10D 64/2527; H10D 84/8311; H10D 84/8312; H10D 84/835; H10D 84/859; H10D 30/0281; H10D 30/0297; H10D 84/0191; H10D 84/0195

(57) ABSTRACT

A semiconductor device includes vertical and lateral transistors respectively disposed in first and second areas of a substrate having a first conductivity type. The vertical transistor includes a first buried layer and a first well region both having a second conductivity type, a first trench, and a second trench. The first buried layer is embedded in the substrate. The first well region is disposed directly above the first buried layer. The first trench extends downward from the first well region into the first buried layer. A conductive portion is disposed in the first trench, in direct contact with the first buried layer, and electrically connected to a drain contact. The second trench is disposed in the first well region. A gate electrode is disposed in the second trench. A source region abuts the second trench.

### BACKGROUND OF THE INVENTION

### 1. Field of the Invention

The present disclosure relates generally to semiconductor technology, and more particularly to semiconductor devices that integrate vertical transistors and lateral transistors in a monolithic substrate.

### 2. Description of Prior Art

With the evolution of integrated circuit manufacturing technology, various components including lateral components (e.g., complementary metal-oxide-semiconductor field-effect transistors (CMOSFET)), in which current flows horizontally, and vertical components (e.g., dynamic random-access memory (DRAM)), in which current flows vertically, may be integrated in a monolithic substrate. The monolithic substrate usually requires a local isolation structure to isolate lateral and vertical components. Generally, a junction isolation region or a partial silicon-on-insulator (partial SOI) region may be used as the local isolation structure. However, the depth of the junction isolation region is limited by the ion implanter's implantation energy. The major processes for forming the partial SOI region include separation by implantation of oxygen (SIMOX) and smart-cut processes, which have many problems that need to be overcome.

### SUMMARY OF THE INVENTION

In view of this, the present disclosure provides semiconductor devices that use a p-type substrate to integrate vertical and lateral transistors. An n-type deep well region and an n-type buried layer are disposed in a first area of the p-type substrate to fabricate a quasi-vertical transistor, and a lateral transistor is fabricated in a second area of the p-type substrate. According to embodiments of the present disclosure, vertical and lateral transistors are integrated in the p-type substrate without requiring a local isolation structure. Therefore, the semiconductor devices avoid problems caused by using junction isolation regions or partial SOI regions as local isolation structures.

According to an embodiment of the present disclosure, a semiconductor device is provided and includes a substrate, a vertical transistor and a lateral transistor. The substrate has a first conductivity type, and includes a first area and a second area. The vertical transistor is disposed in the first area of the substrate. The lateral transistor is disposed in the second area of the substrate. The vertical transistor includes a first buried layer, a first well region, a first trench, a conductive portion, a second trench, a gate electrode and a source region. The first buried layer has a second conductivity type, and is embedded in the substrate. The first well region has the second conductivity type, and is disposed directly above the first buried layer. The first trench extends downward from the first well region into the first buried layer, and the bottom surface of the first trench is located in the first buried layer. The conductive portion is disposed in the first trench, in direct contact with the first buried layer, and electrically coupled to a drain contact. The second trench is disposed in the first well region. The gate electrode is disposed in the second trench. The source region abuts a side of the second trench.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a semiconductor device according to some embodiments of the present disclosure.

FIG. 2 is a schematic cross-sectional view of a semiconductor device according to an embodiment of the present disclosure.

FIG. 3, FIG. 4, FIG. 5, FIG. 6, FIG. 7 and FIG. 8 are schematic cross-sectional views of some intermediate stages of a method of fabricating a semiconductor device according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

According to embodiments of the present disclosure, a p-type substrate is used to integrate vertical transistors and lateral transistors. An n-type deep well region and an n-type buried layer are disposed in a first area of the p-type substrate to fabricate quasi-vertical transistors, and lateral transistors are fabricated in a second area of the p-type substrate. In the semiconductor devices of the present disclosure, vertical transistors and lateral transistors are integrated in a monolithic substrate without a local isolation structure, thereby avoiding associated problems. For example, the local isolation structure may be a junction isolation region or a partial silicon-on-insulator (SOI) region. The depth of a junction isolation region is limited by the ion implanter's implantation energy. Major processes for forming a partial SOI region include smart-cut and etching to form a local oxidation region, followed by epitaxial layer growth. However, these processes of forming the partial SOI region result in epitaxial defects and step-height issues, affecting subsequent processes on the epitaxial layer. For example, exposure process accuracy and the uniformity of etching and grinding processes will be reduced. The semiconductor devices of the present disclosure and fabrication methods thereof avoid the aforementioned problems encountered in conventional local isolation structure formation.

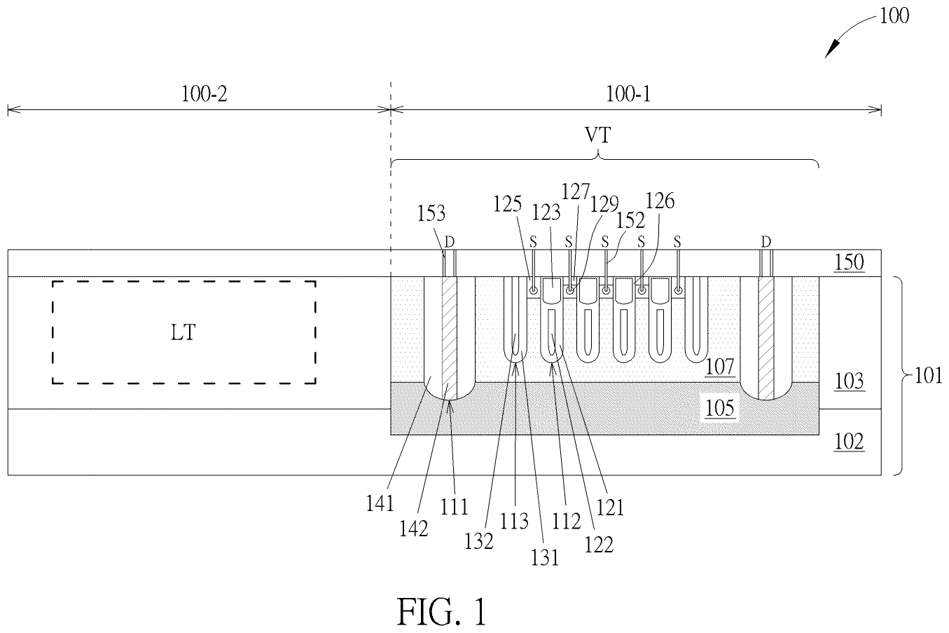

FIG. 1 is a schematic cross-sectional view of a semiconductor device 100 according to some embodiments of the present disclosure. The semiconductor device 100 includes a substrate 101 of a first conductivity type, for example, a p-type semiconductor substrate. In some embodiments, the substrate 101 includes a base 102 and an epitaxial layer 103 stacked on the base 102. The base 102 has the first conductivity type, such as a p-type silicon base, but is not limited thereto. The epitaxial layer 103 also has the first conductivity type, such as a p-type silicon epitaxial layer, but is not limited thereto. In some embodiments, the composition of the base 102 is, for example, silicon (Si), silicon carbide (SiC) or other suitable semiconductor materials. The composition of the epitaxial layer 103 is, for example, silicon (Si), silicon germanium (SiGe), silicon carbide (SiC), gallium nitride (GaN), gallium arsenide (GaAs), indium phosphide (InP) or other suitable semiconductor materials. The doping concentration of first conductive type dopants in the epitaxial layer 103 may be lower than or substantially the same as the doping concentration of first conductive type dopants in the base 102. The epitaxial layer 103 may include one or more sub-epitaxial layers stacked on the base 102. The compositions of these sub-epitaxial layers, the doping concentrations of first conductive type dopants in these sub-epitaxial layers and/or the thicknesses of these sub-epitaxial layers may be different from each other.

The semiconductor device 100 includes a vertical transistor VT and a lateral transistor LT. The substrate 101 includes a first area 100-1 and a second area 100-2. The vertical transistor VT is disposed in the first area 100-1 of the substrate 101, and the lateral transistor LT is disposed in the second area 100-2 of the substrate 101. In some embodiments, the lateral transistor LT may be a bipolar junction transistor (BJT), a complementary metal-oxide-semiconductor (CMOS) transistor, or a double-diffused metal-oxide-semiconductor (DMOS) transistor. In other embodiments, the lateral transistor LT may be a Bipolar-CMOS-DMOS (BCD) integrated structure constructed of a bipolar junction transistor, a CMOS transistor, and a DMOS transistor.

As shown in FIG. 1, in some embodiments, the vertical transistor VT may be a quasi-vertical double-diffused metal-oxide-semiconductor (QVDMOS) transistor that includes a first buried layer 105 and a first well region 107. The first buried layer 105 has a second conductivity type, such as an n-type buried layer (NBL). The first buried layer 105 is embedded in the substrate 101, disposed in the base 102, and extends upward into the epitaxial layer 103. The first well region 107 also has the second conductivity type, such as an n-type deep well region (DNW). The first well region 107 is disposed directly above the first buried layer 105 and in the epitaxial layer 103. In some embodiments, the doping concentration of second conductive type dopants in the first buried layer 105 is higher than the doping concentration of second conductive type dopants in the first well region 107. For example, the doping concentration of the first buried layer 105 may be about 1 E18 to 1 E20 atoms/cm³, and the doping concentration of the first well region 107 may be about 1 E15 to 1 E18 atoms/cm³, but not limited thereto. The first buried layer 105 with a higher doping concentration can reduce the resistance thereof and facilitate current flow in the first buried layer 105. The first well region 107 with a lower doping concentration can increase the breakdown voltage (BV) and reduce the on-state resistance (Ron) of the vertical transistor VT. Moreover, in the vertical projection direction, the side surfaces of the first well region 107 may be aligned with the side surfaces of the first buried layer 105, but is not limited thereto.

The vertical transistor VT includes a first trench 111 extending downward from the top surface of the first well region 107 into the first buried layer 105, so that the bottom surface of the first trench 111 is located in the first buried layer 105. A dielectric layer 141 and a conductive portion 142 are disposed in the first trench 111. The dielectric layer 141 surrounds the side surfaces of the conductive portion 142, and the bottom surface of the conductive portion 142 is exposed, so that the bottom surface of the conductive portion 142 is in direct contact with the first buried layer 105. An interlayer dielectric (ILD) layer 150 is formed on the top surface (also referred to as the front surface) of the substrate 101. A drain contact 153 is disposed in the ILD layer 150 and located directly above the conductive portion 142. The conductive portion 142 is electrically connected to the drain contact 153 and further electrically coupled to a drain potential D.

A main cell area of the vertical transistor VT includes multiple second trenches 112 disposed in the first well region 107. These second trenches 112 extend downward from the top surface of the first well region 107, and the bottom surfaces of these second trenches 112 are located in the first well region 107 and separated from the first buried layer 105 by a distance. A dielectric liner 121, a field plate 122, a gate electrode 123 and a gate dielectric layer 126 are disposed in each of these second trenches 112. The gate electrode 123 is located directly above the field plate 122. The dielectric liner 121 surrounds the side and bottom surfaces of the field plate 122. The gate electrode 123 and the field plate 122 are longitudinally separated by a dielectric material. The gate dielectric layer 126 surrounds the sides of the gate electrode 123. A vertical split-gate trench (SGT) structure is formed in the second trench 112. The vertical transistor VT further includes a third trench 113 disposed in the first well region 107. The third trench 113 is located between the first trench 111 and these second trenches 112. The third trench 113 extends downward from the top surface of the first well region 107, and the bottom surface of the third trench 113 is located in the first well region 107. A dielectric liner 131 and a field plate 132 are disposed in the third trench 113. The dielectric liner 131 surrounds the side and bottom surfaces of the field plate 132.

In some embodiments, the depth of the third trench 113 is the same as the depth of these second trenches 112, and the depth of the first trench 111 is greater than the depth of the third trench 113. In addition, the width of the third trench 113 is the same as the width of these second trenches 112, and the width of the first trench 111 is greater than the width of the third trench 113. Moreover, the thickness of the dielectric liner 131 (also referred to as a first dielectric liner) in the third trench 113 is the same as the thickness of the dielectric liner 121 (also referred to as a second dielectric liner) in the second trench 112, and the thickness of the dielectric layer 141 in the first trench 111 is greater than the thickness of the dielectric liner 131 in the third trench 113. In the semiconductor devices of the present disclosure, the thickness of the dielectric layer 141 in the first trench 111 may be adjusted according to the operating voltage requirements of the vertical transistor VT. When the operating voltage of the vertical transistor VT is higher, the thickness of the dielectric layer 141 is increased, thereby improving the flexibility of the vertical transistor VT's operating voltage range to accommodate various electrical requirements and operating conditions.

In addition, the dielectric liner 131 in the third trench 113 and the dielectric liner 121 in the second trench 112 may have the same composition. The composition of the dielectric layer 141 in the first trench 111 may be different from that of the dielectric liner 131 and the dielectric liner 121. For example, the dielectric liner 121 and the dielectric liner 131 may be composed of silicon oxide, silicon nitride, silicon oxynitride, or a combination thereof, while the dielectric layer 141 may include other high-k materials, such as aluminum oxide (Al₂O₃), hafnium oxide (HfO₂) or zirconium oxide (ZrO₂). In other embodiments, the composition of the dielectric layer 141 may be the same as that of the dielectric liner 131 and the dielectric liner 121. For example, the composition of the dielectric liner 121, the dielectric liner 131 and the dielectric layer 141 may be silicon oxide, silicon nitride, silicon oxynitride or a combination thereof.

In some embodiments, the conductive portion 142 in the third trench 113 may be composed of doped polysilicon with the second conductivity type, such as n-type heavily doped polysilicon, or metal. Using doped polysilicon with the same conductivity type as the first buried layer 105 to form the conductive portion 142 provides a good electrical connection between the conductive portion 142 and the first buried layer 105. Moreover, in subsequent process steps, the conductive portion 142 formed from doped polysilicon will not contaminate or otherwise affect surrounding components. Alternatively, using metal to form the conductive portion 142 effectively reduces the contact resistance between the conductive portion 142 and the first buried layer 105, thereby improving the electrical performances of the vertical transistor VT.

In addition, the vertical transistor VT includes multiple body regions 125 with the first conductive type, such as p-type body regions. The body regions 125 are disposed in the first well region 107. Some of the body regions 125 are located between the second trench 112 and the third trench 113, and other body regions 125 are located between the adjacent second trenches 112. The vertical transistor VT further includes source regions 127 with the second conductivity type, such as n-type heavily doped regions. The source regions 127 are disposed in the body regions 125 between the second trenches 112, abutting the side surfaces of the second trenches 112. The gate dielectric layer 126 in the second trench 112 is located between the gate electrode 123 and the source region 127. A doped region 129 with the first conductivity type, such as a p-type heavily doped region, may be disposed in each body region 125. The doping concentration of the doped region 129 is higher than that of the body region 125. Each of the doped regions 129 is electrically coupled to a source potential S through a respective contact 152. These contacts 152 pass through the ILD layer 150 and are located in the body regions 125. Some of the contacts 152 further pass through the source region 127 to electrically connect the source region 127 to the source potential S. In addition, the gate electrode 123 in the second trench 112 is electrically coupled to a gate potential (not shown) through other contact in the ILD layer 150. In some embodiments, the field plate 122 in the second trench 112 and the field plate 132 in the third trench 113 are both electrically coupled to the source potential S.

In the semiconductor device 100, the current of the vertical transistor VT flows from the drain contact 153 into the conductive portion 142, flows vertically downward through the conductive portion 142, and flows into the first buried layer 105 from the bottom surface of the conductive portion 142. Then, the current of the vertical transistor VT flows horizontally in the first buried layer 105, flows vertically upward along the side of the second trench 112, flows through the first well region 107, and flows out from the source region 127. Therefore, the current of the vertical transistor VT is a quasi-vertical type (or referred to as a U-shaped current).

According to embodiments of the present disclosure, the current of the vertical transistor VT is confined in the first buried layer 105 and the first well region 107, and the U-shaped current flows from the outside to the inside of the vertical transistor VT. Moreover, a junction isolation effect is produced between the p-type substrate 101 and both the n-type first buried layer 105 and the n-type first well region 107. Therefore, according to the semiconductor devices 100 of the present disclosure, good electrical isolation between the vertical transistor VT and the lateral transistor LT is achieved without requiring an additional local isolation structure in the substrate 101.

Furthermore, compared with an n-type substrate, a p-type substrate is more suitable for the lateral transistor LT. In a p-type substrate, the lateral transistor LT does not require an additional junction isolation region or local isolation structure. The semiconductor devices 100 of the present disclosure can integrate the lateral transistor LT and the vertical transistor VT in a monolithic substrate without requiring an additional local isolation structure. Therefore, the fabrication process steps of the semiconductor devices are simplified, and manufacturing costs are reduced, while also avoiding problems caused by forming a local isolation structure. The drain contact 153 of the vertical transistor VT is located on the front side of the substrate 101 via the conductive portion 142. Therefore, no additional back-side electrodes are required on the substrate 101. This reduces the parasitic capacitance of the lateral transistor LT and facilitates the integration of the lateral transistor LT with the vertical transistor VT.

In addition, according to embodiments of the present disclosure, the vertical transistor VT includes the third trench 113 disposed between the first trench 111 at the drain terminal and the second trenches 112 at the source terminal. The third trench 113 is laterally spaced from the first trench 111 and has the field plate 132 disposed therein. The third trench 113 can serve as a termination trench ring surrounding these second trenches 112 in the main cell area. This arrangement of the third trench 113 and the field plate 132 provides good electrical isolation for high-voltage at the drain terminal, thereby making the vertical transistor VT suitable for higher-voltage operating conditions. Moreover, there is no need to form an additional reduced surface electric field (RESURF) doped region on the outer sides of the first trench 111 at the drain terminal. Furthermore, the doped region 129, electrically coupled to the source potential S, is far from the conductive portion 142 at the drain terminal due to the arrangement of the third trench 113, which is beneficial for electric field distribution. No strong electric field is generated near the doped region 129 close to the drain terminal, thereby increasing the breakdown voltage of the vertical transistor VT.

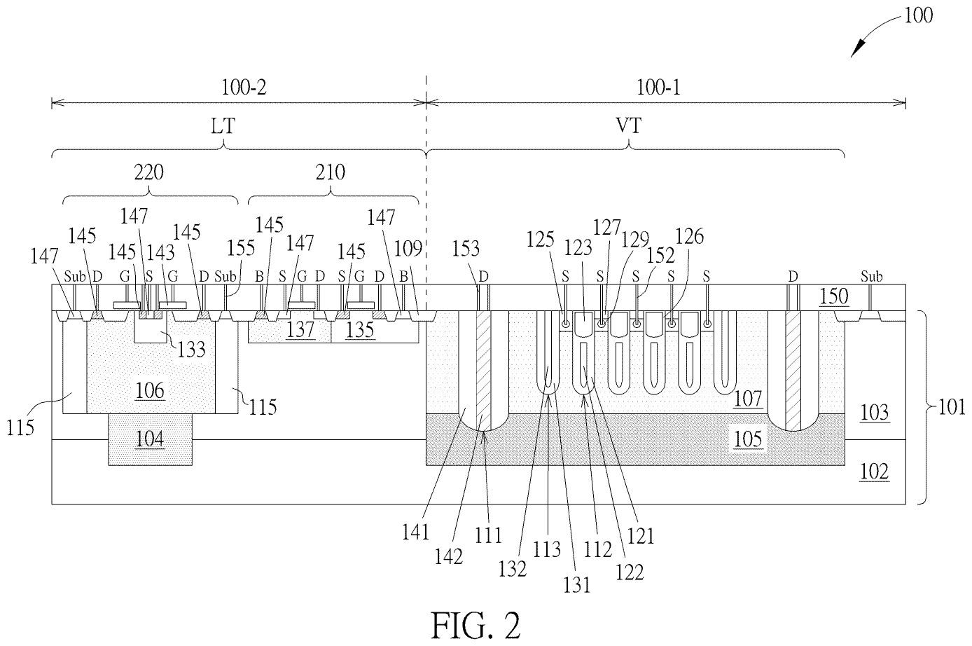

FIG. 2 is a schematic cross-sectional view of a semiconductor device 100 according to an embodiment of the present disclosure. The semiconductor device 100 includes a vertical transistor VT disposed in a first area 100-1 of the substrate 101, and a lateral transistor LT disposed in a second area 100-2 of the substrate 101. The details of the vertical transistor VT may refer to the aforementioned description of FIG. 1, and will not be repeated here. In this embodiment, the lateral transistor LT includes a complementary metal-oxide-semiconductor (CMOS) transistor 210 and a laterally double-diffused metal-oxide-semiconductor (LDMOS) transistor 220, which are disposed in a p-type epitaxial layer 103 of the second area 100-2. The p-type epitaxial layer 103 of the second area 100-2 abuts the side of the first well region 107 and a partial side of the first buried layer 105. The CMOS transistor 210 is located between the LDMOS transistor 220 and the vertical transistor VT. The CMOS transistor 210 includes a p-type well region 135 and an n-type well region 137 that abut each other. Two doped regions 145, such as n-type heavily doped regions, are disposed in the p-type well region 135, and are electrically coupled to a source potential S and a drain potential D, respectively. A doped region 147, such as a p-type heavily doped region, is disposed in the p-type well region 135, and is electrically coupled to a bulk potential B. A gate electrode 143 is disposed on the p-type well region 135, between the two doped regions 145, and is electrically coupled to a gate potential G. In addition, two doped regions 147, such as p-type heavily doped regions, are disposed in the n-type well region 137, and are electrically coupled to the source potential S and the drain potential D, respectively. A doped region 145, such as an n-type heavily doped region, is disposed in the n-type well region 137, and is electrically coupled to the bulk potential B. A gate electrode 143 is disposed on the n-type well region 137, between the two doped regions 147, and is electrically coupled to the gate potential G. This embodiment does not require a second conductive-type junction isolation region directly below both the p-type well region 135 and the n-type well region 137 of the CMOS transistor 210.

In one embodiment, the LDMOS transistor 220 includes a first high-voltage well region 106, a second high-voltage well region 115, a second well region 133, multiple doped regions 145, multiple doped regions 147, and a gate electrode 143. The first high-voltage well region 106 has the second conductivity type, such as an n-type high-voltage well region (HVNW), and is disposed in the p-type epitaxial layer 103. The second well region 133 has the first conductivity type, such as a p-type well region (PW), and is disposed in the first high-voltage well region 106. Two doped regions 145 having the second conductivity type, such as n-type heavily doped regions, and one doped region 147 having the first conductivity type, such as a p-type heavily doped region, are all disposed in the second well region 133 and electrically coupled to a source potential S. Two doped regions 145 having the second conductivity type, such as n-type heavily doped regions, are disposed in the first high-voltage well region 106 and electrically coupled to a drain potential D. The gate electrode 143 is disposed on the top surface of the first high-voltage well region 106, and between the doped region 145 at the source terminal and another doped region 145 at the drain terminal. The second high-voltage well region 115 having the first conductivity type, such as a p-type high-voltage well region (HVPW), surrounds and abuts the first high-voltage well region 106. The doped regions 147 having the first conductivity type, such as p-type heavily doped regions, are disposed in the second high-voltage well region 115 and electrically coupled to a substrate potential Sub. These doped regions 145, these doped regions 147 and the gate electrode 143 of the LDMOS transistor 220 are each electrically coupled to corresponding potentials through multiple contacts 155 in the ILD layer 150.

In addition, the LDMOS transistor 220 may further optionally include a second buried layer 104 of the second conductivity type, such as an n-type buried layer (NBL), directly below the first high-voltage well region 106. The second buried layer 104 can serve as a junction isolation region between the first high-voltage well region 106 of the LDMOS transistor 220 and the p-type substrate 101. In some embodiments, the doping concentration of the second conductive type dopants in the second buried layer 104 may be lower than or the same as the doping concentration of the second conductive type dopants in the first buried layer 105. Furthermore, the semiconductor device 100 may also include multiple shallow trench isolation (STI) regions 109 disposed on the top surface of the substrate 101 to isolate these well regions and doped regions from each other.

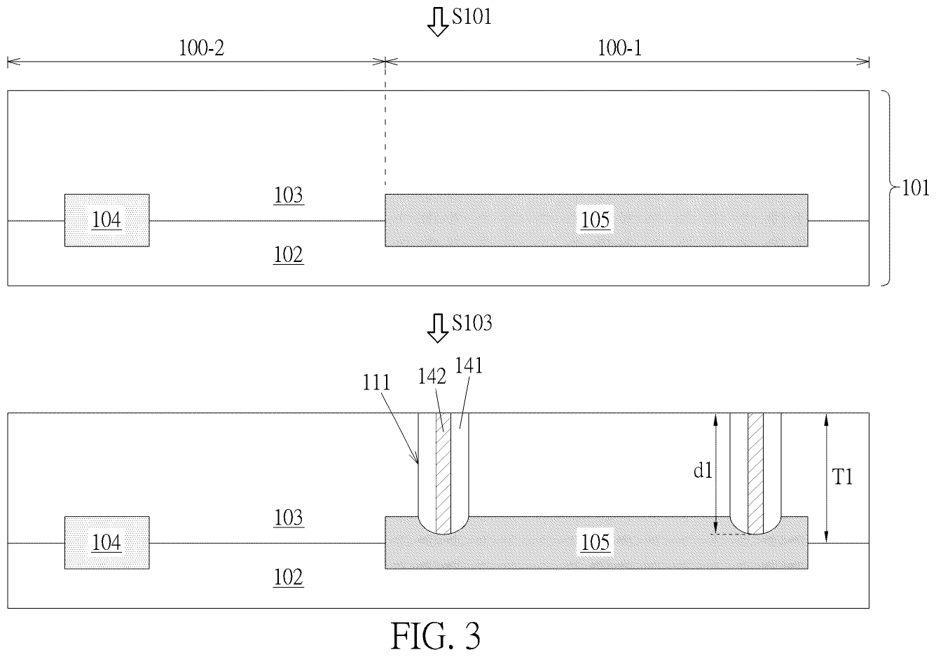

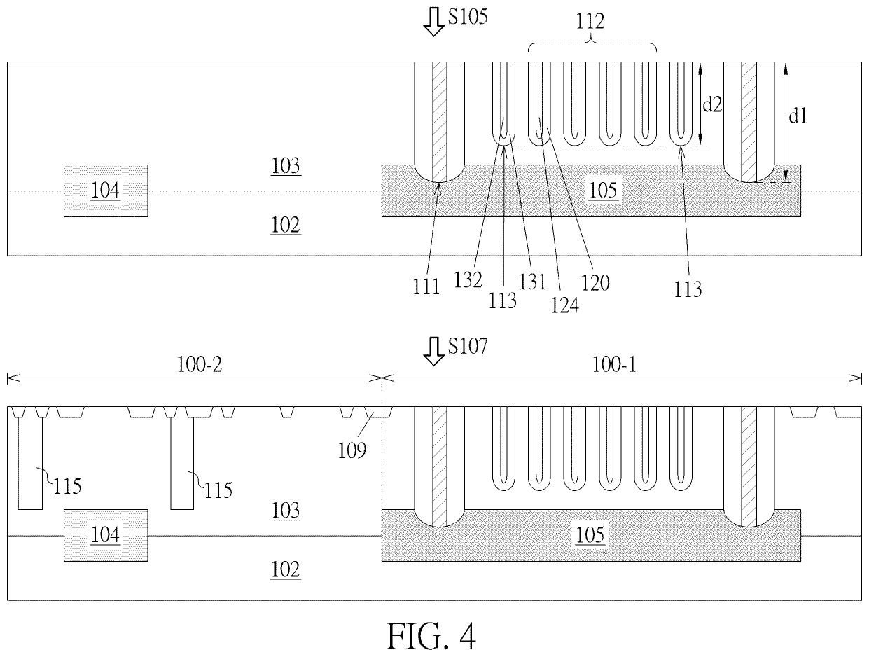

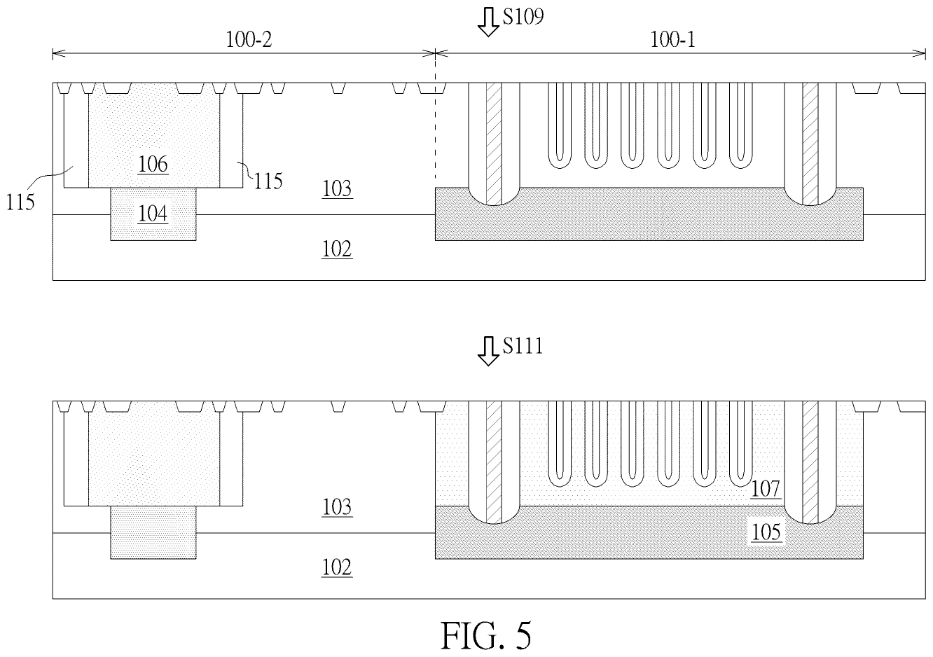

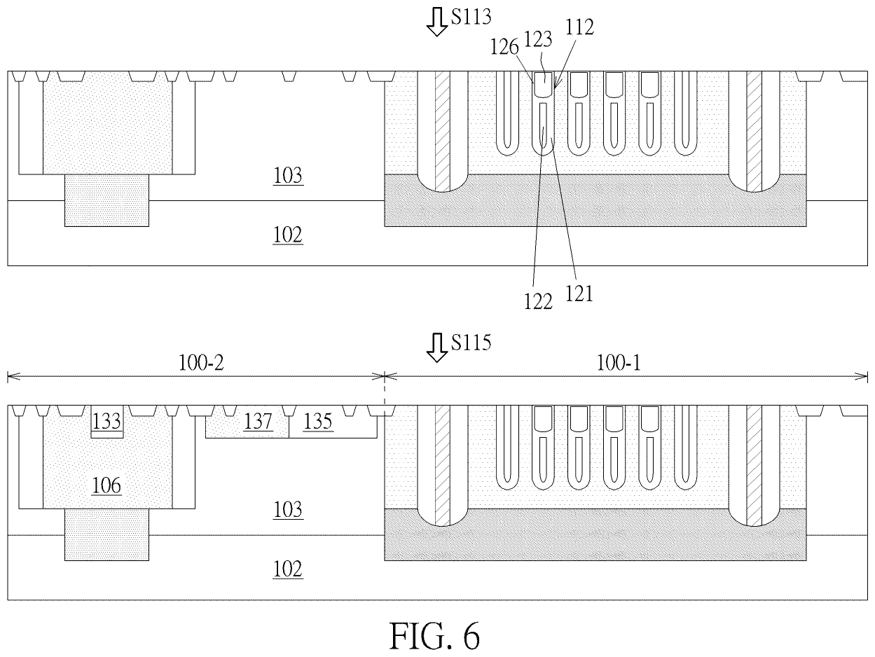

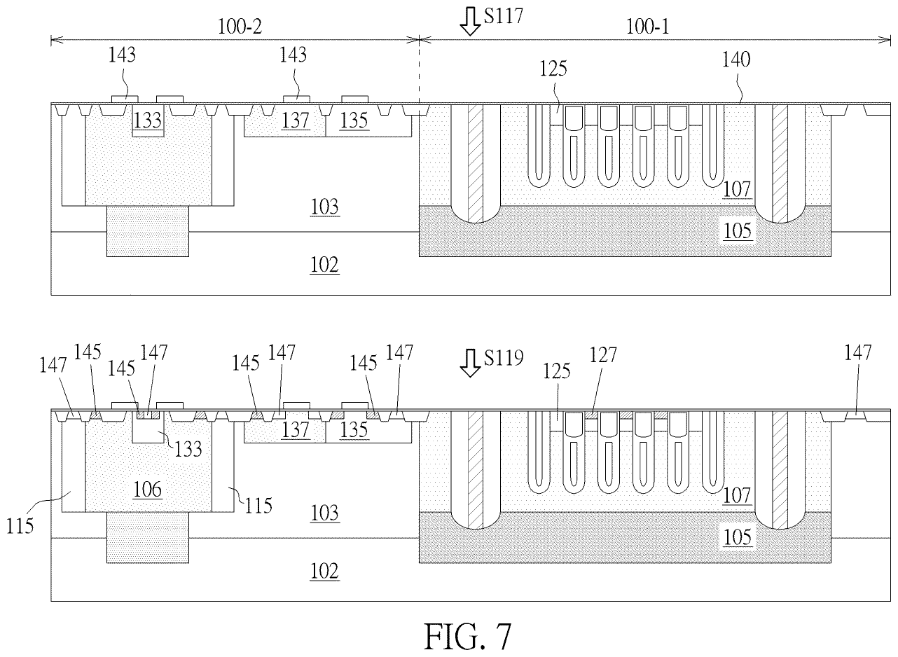

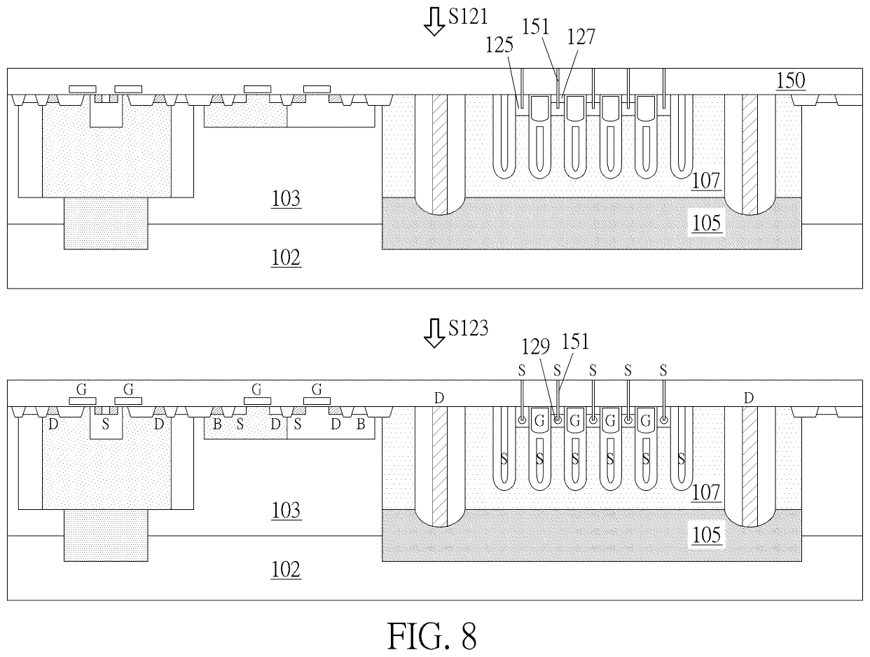

FIG. 3, FIG. 4, FIG. 5, FIG. 6, FIG. 7 and FIG. 8 are schematic cross-sectional views of some intermediate stages of a method of fabricating the semiconductor device 100 of FIG. 2 according to an embodiment of the present disclosure. Referring to FIG. 3, in step S101, firstly, a p-type base 102 is provided, and an n-type second buried layer 104 is formed in a second area 100-2 of the base 102 by ion implantation using a mask. Then, an n-type first buried layer 105 is formed in a first area 100-1 of the base 102 by another ion implantation using another mask. Next, a p-type epitaxial layer 103 is grown on the base 102 by an epitaxial growth process to construct a p-type substrate 101. After the epitaxial growth process, the n-type dopants in both the second buried layer 104 and the first buried layer 105 diffuse from the base 102 into the epitaxial layer 103, so that the second buried layer 104 and the first buried layer 105 are embedded in both the base 102 and the epitaxial layer 103. In some embodiments, the doping concentration of the second buried layer 104 is lower than or the same as the doping concentration of the first buried layer 105.

Still referring to FIG. 3, in step S103, a first trench 111 is formed in the epitaxial layer 103 of the first region 100-1 by etching. The bottom surface of the first trench 111 is located in the first buried layer 105. The first trench 111 has a depth d1, and the epitaxial layer 103 has a thickness T1. In some embodiments, the depth d1 may be less than or substantially equal to the thickness T1. Then, a dielectric layer 142 and a conductive portion 142 are formed in the first trench 111 by deposition and chemical mechanical planarization (CMP) processes.

Next, referring to FIG. 4, in step S105, a third trench 113 and multiple second trenches 112 are simultaneously formed in the epitaxial layer 103 of the first area 100-1 by etching. The third trench 113 surrounds these second trenches 112. The third trench 113 and the second trench 112 have the same depth d2, and the depth d2 is less than the depth d1 of the first trench 111. The bottom surface of the third trench 113 and the bottom surfaces of the second trenches 112 are all spaced from the first buried layer 105. Then, a dielectric liner 131 and a field plate 132 are formed in the third trench 113 by deposition and CMP processes. Meanwhile, a dielectric material layer 120 and a semiconductor material 124 are formed in these second trenches 112 by the aforementioned deposition and CMP processes. The dielectric liner 131 and the dielectric material layer 120 have the same composition and the same thickness. The field plate 132 and the semiconductor material 124 have the same composition and the same dimensions.

Still referring to FIG. 4, in step S107, multiple shallow trench isolation (STI) regions 109 are formed on the top surface of the substrate 101 by etching, deposition and CMP processes. These STI regions 109 are distributed in the first area 100-1 and the second area 100-2. Then, a second high-voltage well region 115, such as a p-type high-voltage well region (HVPW), is formed in the epitaxial layer 103 of the second area 100-2 by ion implantation using a mask.

Referring to FIG. 5, in step S109, a first high-voltage well region 106, such as an n-type high-voltage well region (HVNW), is formed in the epitaxial layer 103 of the second area 100-2 by ion implantation using a mask. The first high-voltage well region 106 is located directly above the second buried layer 104. The second high-voltage well region 115 surrounds and abuts the first high-voltage well region 106. Still referring to FIG. 5, in step S111, a first well region 107, such as an n-type deep well region (DNW), is formed in the epitaxial layer 103 of the first area 100-1 by another ion implantation using another mask. The first well region 107 is located directly above the first buried layer 105. The bottom surface of the first well region 107 is in direct contact with the top surface of the first buried layer 105. In the vertical projection direction, the boundary of the first well region 107 may be aligned with the boundary of the first buried layer 105. In some embodiments, the doping concentration of the first well region 107 is adjusted according to the electrical requirements of the vertical transistor VT, and the doping concentration of the first high-voltage well region 106 is adjusted according to the electrical requirements of the lateral transistor LT. The doping concentrations of the first well region 107 and the first high-voltage well region 106 may be independent of each other.

Next, referring to FIG. 6, in step S113, an upper portion of the semiconductor material 124 in the second trench 112 is removed by etching to form the field plate 122. Then, the second trench 112 is filled with a dielectric material by deposition to cover the field plate 122. The dielectric material located above the field plate 122 in the second trench 112 is etched to form a recess, and a gate dielectric layer 126 is conformally formed in the recess by deposition or thermal oxidation. Afterwards, the recess is filled up with semiconductor material to form a gate electrode 123. The remaining dielectric material layer 120 in the second trench 112 forms a dielectric liner 121 surrounding the field plate 122. The filled dielectric material longitudinally separates the gate electrode 123 and the field plate 122.

Still referring to FIG. 6, in step S115, a p-type well region 135 is formed in the epitaxial layer 103 of the second area 100-2 by ion implantation process using a mask. Meanwhile, a p-type second well region 133 is formed in the first high-voltage well region 106 by the aforementioned ion implantation using the same mask. Next, an n-type well region 137 is formed in the epitaxial layer 103 of the second area 100-2 by another ion implantation using another mask. The n-type well region 137 abuts the p-type well region 135.

Then, referring to FIG. 7, in step S117, a dielectric layer 140 is deposited on the entire top surface of the substrate 101. The dielectric layer 140 located in the second area 100-2 serves as a gate dielectric layer. Next, multiple gate electrodes 143 are formed on the dielectric layer 140 of the second area 100-2 by deposition and patterning processes. Two of these gate electrodes 143 are located on both sides of the second well region 133. Other two of these gate electrodes 143 are located directly above the p-type well region 135 and the n-type well region 137 respectively. Afterwards, multiple body regions 125 such as p-type body regions are formed in the first well region 107 of the first area 100-1 by ion implantation using a mask. These body regions 125 are located on two sides of each gate electrode 123.

Still referring to FIG. 7, in step S119, multiple doped regions 145, such as n-type heavily doped regions, are simultaneously formed in the p-type well region 135, the n-type well region 137, the first high-voltage well region 106 and the second well region 133 by ion implantation using a mask. Meanwhile, multiple source regions 127 are respectively formed in the body regions 125 by the aforementioned ion implantation using the same mask. Then, multiple doped regions 147 such as p-type heavily doped regions are simultaneously formed in the epitaxial layer 103 of the first area 100-1, the p-type well region 135, the n-type well region 137, the second high-voltage well region 115 and the second well region 133 by another ion implantation using another mask.

Next, referring to FIG. 8, in step S121, an ILD layer 150 is deposited on the entire top surface of the substrate 101 to cover these gate electrodes 143. Then, multiple openings 151 are formed in the ILD layer 150 of the first area 100-1 by etching. These openings 151 extend downward into the body regions 125, and some of these openings 151 pass through the source regions 127. Still referring to FIG. 8, in step S123, multiple doped regions 129, such as p-type heavily doped regions, are formed in the body regions 125 through the openings 151 by ion implantation. These doped regions 129 are located directly below the openings 151.

Thereafter, referring to FIG. 2, the openings 151 are filled up with conductive material to form multiple contacts 152 of the vertical transistor VT. Next, openings for drain contacts 153 are formed in the ILD layer 150 of the first area 100-1 by etching. Meanwhile, openings for multiple contacts 155 are formed in the ILD layer 150 of the second area 100-2 by the aforementioned etching. Then, the openings of the drain contacts 153 and the openings of the contacts 155 are filled up with the same conductive material to form the drain contacts 153 of the vertical transistor VT, the contacts 155 of the CMOS transistor 210, and the contacts 155 of the LDMOS transistor 220, thereby completing the semiconductor device 100 of FIG. 2. To facilitate understanding, the gate potential G, the source potential S, and the drain potential D of the vertical transistor VT, the gate potential G, the source potential S, and the drain potential D, and the bulk potential B of the CMOS transistor 210, and the gate potential G, the source potential S, and the drain potential D of the LDMOS transistor 220 are marked in FIG. 8.

According to the embodiments of the present disclosure, an n-type deep well region and an n-type buried layer are disposed in a first area of a p-type substrate to fabricate a vertical transistor, and a lateral transistor is fabricated in a second area of the p-type substrate. Because the current of the vertical transistor is confined in the n-type deep well region and the n-type buried layer, the vertical transistor and the lateral transistor are integrated in a monolithic substrate without requiring a local isolation structure in the p-type substrate. This avoids problems associated with forming a local isolation structure. The manufacturing process of the semiconductor devices of the present disclosure is simplified, and the manufacturing cost is reduced. Moreover, in the semiconductor devices of the present disclosure, the arrangement of the third trench and the field plate is helpful for the vertical transistor suitable for high-voltage operating (e.g., greater than 80V), and the breakdown voltage of the vertical transistor is improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate, having a first conductivity type and comprising a first area and a second area;
a vertical transistor, disposed in the first area of the substrate, and comprising:
a first buried layer, having a second conductivity type, and embedded in the substrate;
a first well region, having the second conductivity type, and disposed directly above the first buried layer;
a first trench, extending downward from the first well region into the first buried layer, wherein a bottom surface of the first trench is located in the first buried layer;
a conductive portion, disposed in the first trench, in direct contact with the first buried layer, and electrically coupled to a drain contact;
a second trench, disposed in the first well region;
a gate electrode, disposed in the second trench; and
a source region, abutting a side of the second trench; and
a lateral transistor, disposed in the second area of the substrate.

2. The semiconductor device of claim 1, wherein the vertical transistor further comprises:
a third trench, disposed in the first well region, and between the first trench and the second trench;
a first field plate, disposed in the third trench; and
a first dielectric liner, disposed in the third trench and surrounding side surfaces and a bottom surface of the first field plate.

3. The semiconductor device of claim 2, wherein a depth of the third trench is the same as a depth of the second trench, and a depth of the first trench is greater than the depth of the third trench.

4. The semiconductor device of claim 2, wherein a width of the third trench is the same as a width of the second trench, and a width of the first trench is greater than the width of the third trench.

5. The semiconductor device of claim 2, wherein the vertical transistor further comprises:
a second field plate, disposed in the second trench, located directly below and longitudinally separated from the gate electrode; and
a second dielectric liner, disposed in the second trench, and surrounding side surfaces and a bottom surface of the second field plate, wherein a thickness of the second dielectric liner is the same as a thickness of the first dielectric liner.

6. The semiconductor device of claim 2, wherein the vertical transistor further comprises:
a dielectric layer, disposed in the first trench, surrounding side surfaces of the conductive portion, and exposing a bottom surface of the conductive portion,
wherein a thickness of the dielectric layer is greater than a thickness of the first dielectric liner.

7. The semiconductor device of claim 2, wherein the vertical transistor further comprises:
a body region, having the first conductivity type, disposed in the first well region, and between the second trench and the third trench; and
a doped region, having the first conductivity type, disposed in the body region, wherein a doping concentration of the doped region is higher than a doping concentration of the body region, and the doped region is configured to be electrically coupled to a source potential.

8. The semiconductor device of claim 1, wherein a doping concentration of the first buried layer is higher than a doping concentration of the first well region.

9. The semiconductor device of claim 1, wherein the substrate comprises a p-type epitaxial layer stacked on a p-type base.

10. The semiconductor device of claim 9, wherein the p-type epitaxial layer of the second area abuts a side surface of the first well region and a partial side surface of the first buried layer.

11. The semiconductor device of claim 9, wherein the lateral transistor comprises a complementary metal-oxide-semiconductor transistor disposed in the p-type epitaxial layer of the second area.

12. The semiconductor device of claim 11, further comprising a laterally double-diffused metal-oxide-semiconductor transistor disposed in the p-type epitaxial layer of the second area, wherein the complementary metal-oxide-semiconductor transistor is located between the laterally double-diffused metal-oxide-semiconductor transistor and the vertical transistor.

13. The semiconductor device of claim 12, wherein the laterally double-diffused metal-oxide-semiconductor transistor comprises:
a first high-voltage well region, having the second conductivity type;
a second well region, having the first conductivity type, and disposed in the first high-voltage well region;
a first doped region, having the second conductivity type, disposed in the second well region, and configured to be electrically coupled to a source potential; and
a second doped region, having the second conductivity type, disposed in the first high-voltage well region, and configured to be electrically coupled to a drain potential.

14. The semiconductor device of claim 13, wherein the laterally double-diffused metal-oxide-semiconductor transistor further comprises:
a second high-voltage well region, having the first conductivity type, surrounding and abutting the first high-voltage well region; and
a third doped region, having the first conductivity type, disposed in the second high-voltage well region, and configured to be electrically coupled to a substrate potential.

15. The semiconductor device of claim 13, further comprising a second buried layer, having the second conductivity type, and disposed directly below the first high-voltage well region.

16. The semiconductor device of claim 15, wherein a doping concentration of the second buried layer is lower than a doping concentration of the first buried layer.

17. The semiconductor device of claim 1, wherein a composition of the conductive portion comprises a doped polysilicon having the second conductivity type, or a metal.

18. The semiconductor device of claim 1, wherein the drain contact of the vertical transistor is disposed directly above the conductive portion and on a surface of the substrate.

19. The semiconductor device of claim 1, wherein a current of the vertical transistor flows from the drain contact into the conductive portion, flows vertically downward through the conductive portion, flows into the first buried layer from a bottom surface of the conductive portion, flows horizontally in the first buried layer, flows vertically upward along a side of the second trench, flows through the first well region, and flows out from the source region.

20. The semiconductor device of claim 1, wherein in a vertical projection direction, side surfaces of the first well region are aligned with side surfaces of the first buried layer.
